(19) United States
(12) Patent Application Publication
(10) Pub. No.: US 2007/0187771 A1
(43) Pub. Date: Aug. 16, 2007

(54) Semiconductor device and method of manufacturing the same

(75) Inventor: Eiji Takaike, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/707,152

(22) Filed: Feb. 16, 2007

(30) Foreign Application Priority Data
Feb. 16, 2006 (JP) P2006-039161

(51) Int. Cl. H01L 29/94

(52) U.S. Cl. 257/369

(57) ABSTRACT

In a semiconductor device 10, an electrode terminal 18 of a semiconductor element 14 embedded in an insulating layer 12 formed by a resin forming a substrate and a land portion 20 forming an external connecting terminal are electrically connected to each other through a wiring pattern 22 formed on the insulating layer 12. The wiring pattern 22 including the land portion 20 is formed by a plating metal 26. A metallic wire 24 having one of ends connected to the electrode terminal 18 is provided in the plating metal 26 along the wiring pattern 22.

This application claims priority to Japanese Patent Application No. 2006-039161, filed Feb. 16, 2006, in the Japanese Patent Office. The priority application is incorporated by reference in its entirety.

### TECHNICAL FIELD

The present disclosure relates to a semiconductor device and a method of manufacturing the semiconductor device. More particularly, the present disclosure relates to a semiconductor device in which an electrode terminal of a semiconductor element embedded in an insulating layer formed by a resin forming a substrate and a land portion forming an external connecting terminal are electrically connected to each other through a wiring pattern formed on the insulating layer, and a method of manufacturing the semiconductor device.

### RELATED ART

In a semiconductor device, an electrode terminal of a semiconductor element mounted on a substrate and an external connecting terminal provided on the substrate are electrically connected to each other through a wiring pattern formed on the substrate. The wiring pattern is formed of a plating metal through electrolytic plating. For the plating metal, copper having a low specific resistance is generally used.

In recent years, a resin substrate for which an insulating layer formed by a resin is used is generally utilized for a substrate to be used in the semiconductor device.

However, copper forming the wiring pattern and a resin forming the substrate have a great difference in a coefficient of thermal expansion, and a stress generated by the difference in a coefficient of thermal expansion from the resin substrate is applied to a wiring pattern formed of copper.

On the other hand, an enhancement in a fineness of the wiring pattern progresses in order to meet the needs for a reduction in a size of the semiconductor device and an increase in an integration. Consequently, there is a possibility that the wiring pattern might be disconnected due to the stress generated by the difference in a coefficient of thermal expansion between the resin substrate and the wiring pattern.

In contrast to the related-art semiconductor device, Patent Document 1 (Japanese Patent Unexamined Publication No. Hei. 11-163217) has proposed a semiconductor device in which an electrode terminal of a semiconductor element mounted on a substrate and an external connecting terminal provided on the substrate are electrically connected to each other through a wire formed of gold (a gold wire).

According to the semiconductor device proposed in the Patent Document 1, a wire is hard to disconnect with a stress based on a difference in a coefficient of thermal expansion between a wire and a resin substrate.

However, a gold wire having an excellent handling property is generally used as a wire. Since gold has a higher specific resistance than copper, it is required that a wiring pattern formed of copper having an excellent electrical characteristic is employed.

In a related-art semiconductor device, moreover, a semiconductor element is mounted on a wiring board. Therefore, a thickness of the semiconductor device is apt to be increased. On the other hand, as the semiconductor device to be used for a cell phone, it is demanded that a semiconductor device has a thickness which is as small as possible.

### SUMMARY

Embodiments of the present invention provide a semiconductor device in which a thickness can be reduced as greatly as possible and there is formed a wiring pattern which is hard to disconnect even if a stress caused by a difference in a coefficient of thermal expansion between an insulating layer formed by a resin and the wiring pattern is applied.

The inventor made investigations to attain the object. As a result, he found that a wiring pattern having a gold wire provided therein and formed of plating copper is hard to disconnect even if a stress caused by a difference in a coefficient of thermal expansion from a resin substrate is applied, and also has an excellent electrical characteristic and thus reached the present invention.

More specifically, according to one or more embodiments of the present invention, a semiconductor device comprises: an insulating layer formed by a resin forming a substrate; a semiconductor element embedded in the insulating layer; a wiring pattern formed on the insulating layer and electrically connecting an electrode terminal of the semiconductor element and a land portion forming an external connecting terminal, wherein the wiring pattern including the land portion is formed of a plating metal, wherein at least one of a metallic wire having one of ends connected to the electrode terminal or the land portion and a plurality of metallic bumps erected on the insulating layer or the electrode terminal is provided in the plating metal along the wiring pattern.

Moreover, according to one or more embodiments of the present invention, a method of manufacturing a semiconductor device comprises steps of: mounting a semiconductor element on one surface side of a support plate, embedding the semiconductor element in an insulating layer formed by a resin forming a substrate, and then carrying out patterning over the insulating layer to expose an electrode terminal of the semiconductor element; forming a metallic thin film on a whole surface of the insulating layer including an exposed surface of the electrode terminal, and then disposing at least one of a metallic wire having one of ends connected to the electrode terminal or a portion in which a land portion forming an external connecting terminal is to be formed and a plurality of metallic bumps erected on the insulating layer or the electrode terminal along a shape of a wiring pattern to be formed; and forming the wiring pattern formed of a plating metal in which at least one of the wire and the bump is disposed through electrolytic plating using the metallic thin film as a power feeding layer so that the electrode terminal and the land portion are electrically connected to each other through the wiring pattern.

In one or more embodiments of the present invention, the wiring pattern is formed of a plating metal having a lower specific resistance than metals forming the wire and the bump. Consequently, it is possible to enhance an electrical characteristic of the wiring pattern.

The wire has one of ends connected to the electrode terminal of the semiconductor element, and the other end of the wire is extended to a portion in which the land portion for the external connecting terminal is to be formed. Consequently, it is possible to disconnect the wiring pattern with much more difficulty. Moreover, the bump can easily be formed by using a wire.

It is possible to directly laminate another semiconductor device by also forming the land portion forming the external connecting terminal of the semiconductor device according to the present invention on an opposite surface side to an electrode terminal formation surface on which the electrode terminal of the semiconductor element is formed.

Furthermore, it is possible to suitably use a semiconductor element having a smaller area of the electrode terminal formation surface on which the electrode terminal is formed than an area of an external connecting terminal formation surface of the substrate forming the external connecting terminal.

One or more embodiments of the present invention may include one or more the following advantages. For example, according to the semiconductor device of one or more embodiments of the present invention, at least one of the metallic wire and the metallic bumps erected on the insulating layer is provided in the wiring pattern formed by the plating metal formed on the insulating layer formed by the resin. For this reason, even if a stress caused by a difference in a coefficient of thermal expansion between the insulating layer and the wiring pattern is applied to the wiring pattern, it is possible to eliminate a possibility that the wiring pattern reinforced by at least one of the wire and the bump might be disconnected.

In the case in which one of the ends of the metallic wire is connected to the electrode terminal of the semiconductor element, it is also possible to prevent the wiring pattern from being separated from the electrode terminal.

In one or more embodiments of the present invention, furthermore, the semiconductor element is embedded in the insulating layer forming the substrate. Therefore, it is possible to cause the thickness of the semiconductor device to be smaller than that of a semiconductor device in which a semiconductor element is mounted on a substrate.

As a result, according to the semiconductor device in accordance with the present invention, it is possible to enhance a reliability of the wiring pattern and to cause a thickness to be smaller than that of a related-art semiconductor device.

Also in the semiconductor device according to one or more embodiments of the present invention, moreover, in the case in which the wiring pattern is formed of a plating metal having a lower specific resistance than the metals forming the wire and the bump, it is possible to obtain almost the same electrical characteristic as that of the wiring pattern formed by only the plating metal having a low specific resistance.

Other features and advantages may be apparent from the following detailed description, the accompanying drawings and the claims.

### BRIEF DESCRIPTION OF THE DRAWINGS

FIG. 1A is a rear view showing a back state of a semiconductor device according to an exemplary embodiment of the present invention,

FIG. 1B is a front view showing a surface state of an insulating layer from which a solder resist of the surface is removed,

FIG. 2 is an enlarged cross-sectional view showing the semiconductor device illustrated in FIG. 1A from which solder balls ere removed,

FIGS. 3A to 3C are views for explaining a part of a process for manufacturing the semiconductor device illustrated in FIG. 2,

FIGS. 4A to 4D are views for explaining a part of the process for manufacturing the semiconductor device illustrated in FIG. 2,

FIGS. 5A, 5B are views for explaining a part of the process for manufacturing the semiconductor device illustrated in FIG. 2,

FIGS. 6A, 6B are views for explaining a part of a process for manufacturing a semiconductor device according to another exemplary embodiment of a method of manufacturing a semiconductor device according to the present invention,

FIG. 7 is an enlarged cross-sectional view showing a semiconductor device obtained in the manufacturing process illustrated in FIG. 6,

FIG. 8 is an enlarged cross-sectional view showing a semiconductor device according to a further exemplary embodiment of the present invention,

FIGS. 9A to 9C are views for explaining a part of a process for manufacturing the semiconductor device illustrated in FIG. 8, and

FIGS. 10A to 10E are views for explaining a part of the process for manufacturing the semiconductor device illustrated in FIG. 8.

### DETAILED DESCRIPTION

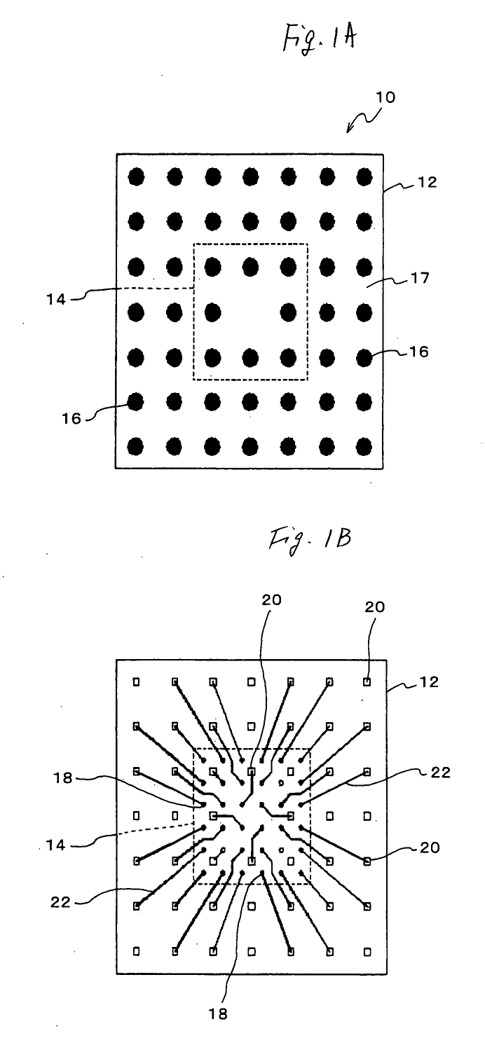

FIG. 1 shows an exemplary embodiment of a semiconductor device according to the present invention. FIG. 1A is a front view showing a ball side on which solder balls 16, 16 to be external connecting terminals of a semiconductor device 10 are provided over a whole surface. A semiconductor element 14 is embedded in an insulating layer 12 formed by a resin such as epoxy or polyimide in an almost central part of the semiconductor device 10. A surface of the insulating layer 12 is covered with a solder resist 17 except for the solder ball 16, 16 portions.

FIG. 1B shows a surface state of the insulating layer 12 from which the solder resist 17 is removed. An electrode terminal 18 of the semiconductor element 14 embedded in the insulating layer 12 and a land portion 20 on which the solder ball 16 is provided are electrically connected to each other through a wiring pattern 22. The land portion 20 is also formed above the semiconductor element 14.

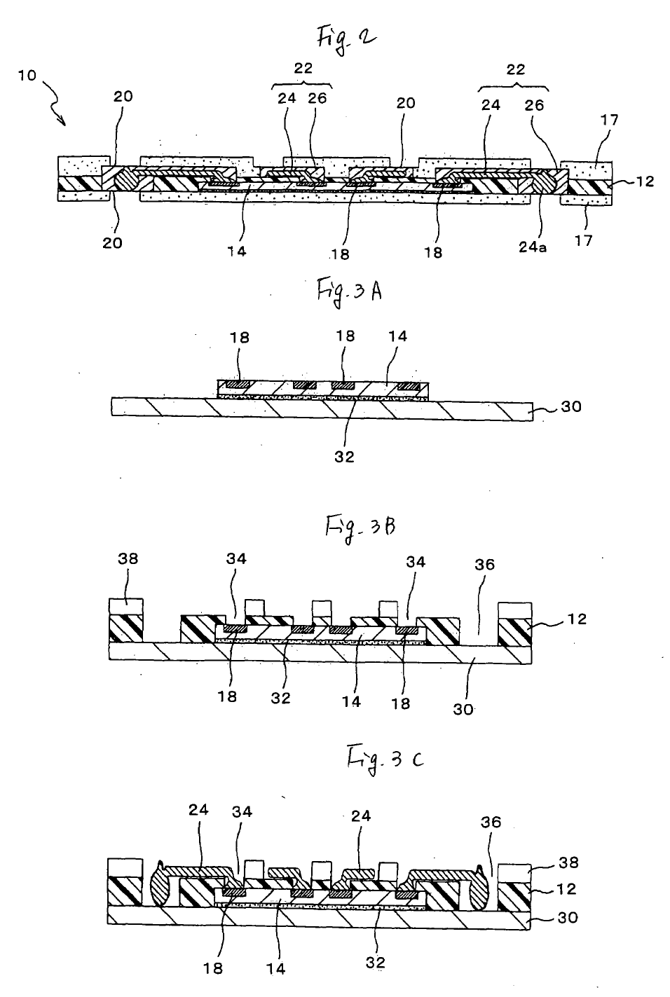

FIG. 2 is an enlarged cross-sectional view showing the semiconductor device 10 illustrated in FIG. 1A from which the solder balls 16 is removed. The wiring pattern 22 for electrically connecting the electrode terminal 18 of the semiconductor element 14 embedded in the insulating layer 12 formed by a resin which mainly forms the semiconductor device 10 to the land portion 20 on which the solder ball 16 is provided is formed on the surface of the insulating layer 12. In the wiring pattern 22, a wire 24 having one of ends connected to the electrode terminal 18 of the semiconductor element 14 and formed of gold (which will be hereinafter referred to as a wire 24) is provided in a plating metal 26 formed of copper. The other end of the wire 24 is extended into the land portion 20.

An insulating layer formed by a resin such as epoxy or polyimide may be formed in place of the solder resist layer 17.

Since the wiring pattern 22 is formed by the plating metal 26 constituted mainly by copper, it has the same electrical characteristic as that of a wiring pattern formed of only copper.

In addition, the wiring pattern 22 has the wire 24 provided in the plating metal 26. Even if a stress caused by a difference in a coefficient of thermal expansion from the insulating layer 12 is applied, therefore, it is possible to eliminate a possibility of a disconnection. Thus, it is possible to enhance a reliability of the semiconductor device 10.

In the semiconductor device 10, moreover, the semiconductor element 14 is embedded in the insulating layer 12 which mainly forms the semiconductor device 10. Therefore, it is possible to cause a thickness to be smaller than that in a related-art semiconductor device in which a semiconductor element is mounted on a wiring board.

In the vicinity of an outer peripheral edge of the insulating layer 12 of the semiconductor device 10 shown in FIGS. 1 and 2, furthermore, the land portions 20 and 20 are formed on both surface sides of the insulating layer 12. The other end of the wire 24 extended into the land portions 20 and 20 which are formed on both surface sides of the insulating layer 12 is formed into a spherical portion 24a having a larger diameter than a diameter of the wire 24.

Thus, the land portions 20, 20 . . . are formed on both surface sides of the semiconductor device 10. Consequently, the solder balls 16, 16 to be external connecting terminals are provided in the land portions 20, 20 . . . formed on one surface side, and an external connecting terminal of an electronic component of other semiconductor devices can be connected to the land portions 20, 20 . . . formed on the other surface side.

When manufacturing the semiconductor device 10 shown in FIGS. 1 and 2, first of all, a semiconductor element 14 is bonded to one surface side of a metallic support plate 30 with an adhesive 32 as shown in FIG. 3A and an insulating layer 12 covering a mounting surface of the support plate 30 having the semiconductor element 14 mounted thereon is then formed by a resin such as polyimide and the semiconductor element 14 is embedded in the insulating layer 12.

Furthermore, the insulating layer 12 is subjected to patterning through etching or a laser, thereby forming a concave portion 34 having a bottom face to which the electrode terminal 18 of the semiconductor element 14 is exposed and forming a concave portion 36 having a bottom face to which the support plate 30 is exposed in the vicinity of an outer peripheral edge of the insulating layer 12.

A metallic thin film (not shown) is formed on a whole surface of the insulating layer 12 subjected to the patterning, an exposed surface of the electrode terminal 18 and an exposed surface of the support plate 30 through nonelectrolytic plating or evaporation. As shown in FIG. 3B, then, a pattern conforming to wiring patterns 22, 22 . . . is formed on the insulating layer 12 through a plating resist 38.

As shown in FIG. 3C, subsequently, a wire 24 having one of ends connected to the electrode terminal 18 of the semiconductor element 14 exposed to a bottom face of the concave portion 34 is extended to a position of the corresponding land portion 20 along the pattern formed in conformity to the wiring pattern 22 through the plating resist 38. For the connection and extension of the wire 24, it is possible to employ a bonding apparatus to be used at a wire bonding step in a process for manufacturing a semiconductor device. In the bonding apparatus, a tip portion of the wire 24 held by clamp means is welded to the electrode terminal 18 of the semiconductor element 14 and the wire 24 is then pulled out, and at the same time, is moved along the pattern formed by the plating resist 38 and a portion of the wire 24 placed on the position of the land portion 20 to be formed is fused.

In this case, the other end of the wire 24 is welded and fused to an exposed surface of a metallic thin film formed on the support plate 30 exposed to the bottom face of the concave portion 36. For this reason, the other end of the wire 24 welded to the exposed surface of the metallic thin film on the support plate 30 is formed into a thicker spherical portion than the wire 24.

On the other hand, in the wiring pattern 22 in which the land portion 20 is formed above the semiconductor element 14, the other end of the wire 24 is fused to the metallic thin film provided on the insulating layer 12 in a non-contact state.

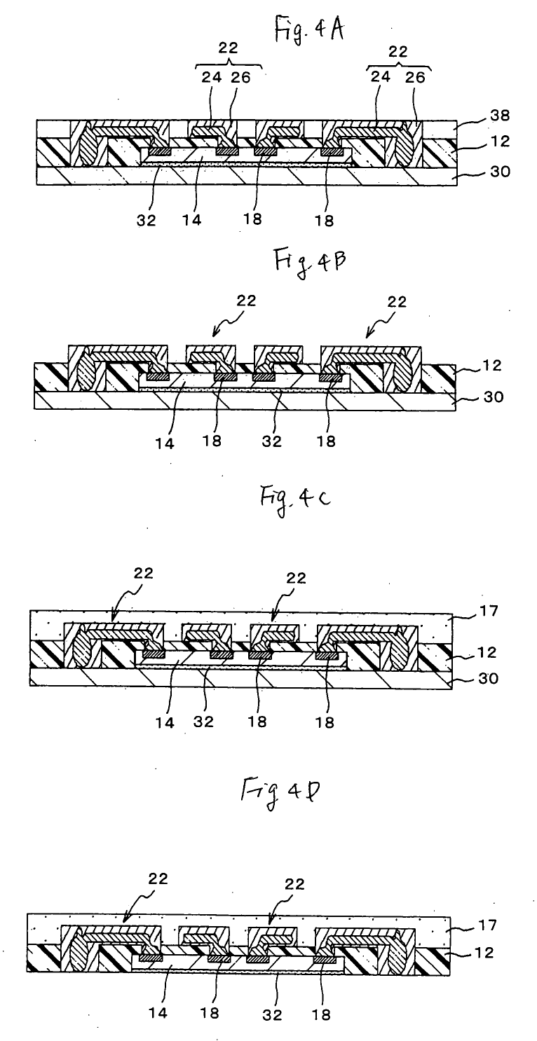

Plating copper is filled as a plating metal 26 in the pattern formed by the plating resist 38 through electrolytic copper plating using the support plate 30 and the metallic thin film (not shown) as power feeding layers, thereby forming the wiring pattern 22 on the surface side of the insulating layer 12 provided with the wires 24, 24 as shown in FIG. 3C [a step in FIG. 4A].

After the electrolytic copper plating for forming the wiring pattern 22 is carried out, the plating resist 38 is removed and the metallic thin film (not shown) exposed to the surface of the insulating layer 12 is removed by etching [a step in FIG. 4B]. By the removal of the metallic thin film, middle portions of the wiring patterns 22, 22 can be insulated electrically.

Subsequently, the exposed surface of the insulating layer 12 from which the metallic thin film is removed and the wiring pattern 22 are covered with a solder resist 17 and the support plate 30 is then removed by the etching [steps in FIGS. 4C and 4D].

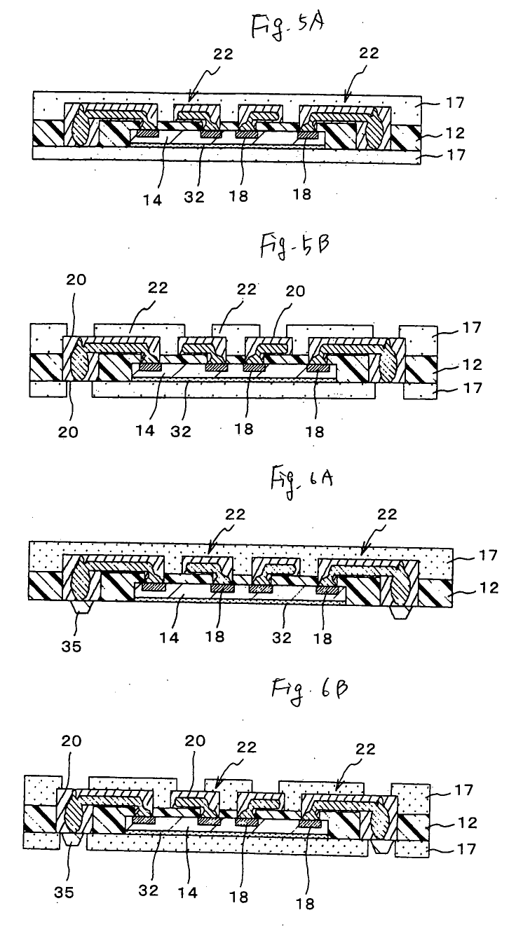

Next, the exposed surface of the insulating layer 12 which is exposed by removing the support plate 30 is covered with the solder resist 17. Thereafter, the solder resists 17, 17 . . . are subjected to patterning to expose the land portions 20, 20-[steps in FIGS. 5A and 5B].

In the semiconductor device obtained by completing the step in FIG. 5B, the land portions 20, 20 are formed on both surface sides. As shown in FIG. 1A, a solder ball 16 to be an external connecting terminal can be provided on each of exposed surfaces of the land portions 20, 20 . . . which are provided on a surface side of the semiconductor element 14 on which the electrode terminals 18, 18 are formed.

On the other hand, the solder ball 16 may be provided in the land portions 20, 20 . . . formed on an opposite surface side to the surface of the semiconductor element 14 on which the electrode terminals 18, 18 . . . are formed or an external connecting terminal of an electronic component of other semiconductor devices may be connected thereto.

In the method of manufacturing the semiconductor device shown in FIGS. 3 to 5, the support plate 30 is perfectly removed. As shown in FIG. 6A, however, a part of the support plate 30 can also be left as a bump 35 in the etching. Thus, the exposed surface of the insulating layer 12 which is exposed with the bump 35 left is covered with the solder resist 17, and patterning is then carried out over the solder resist 17 on the surface side of the semiconductor element 14 on which the electrode terminals 18, 18 are formed, and each of surfaces of the land portions 20, 20 . . . is exposed [a step in FIG. 6B].

As shown in FIG. 7, thereafter, the solder ball 16 to be the external connecting terminal is provided on each of the exposed surfaces of the land portions 20, 20 . . . at the surface side of the semiconductor element 14 on which the electrodes 18, 18 . . . are formed. Consequently, it is possible to form a bump on each of the exposed surfaces of the land portions 20, 20 . . . at both surface sides of the semiconductor device 10.

While the wiring patterns 22, 22 . . . having the wire 24 provided in the plating metal are formed in the semiconductor device shown in FIGS. 1 to 7, it is also possible to form a plurality of metallic bumps in place of the wire 24. As shown in FIG. 3B, after the metallic thin film is formed on the whole surface of the insulating layer 12 subjected to the patterning, the exposed surface of the electrode terminal 18 and the exposed surface of the support plate 30, it is possible to form the bump by using the wire 24 along the wiring pattern to be provided.

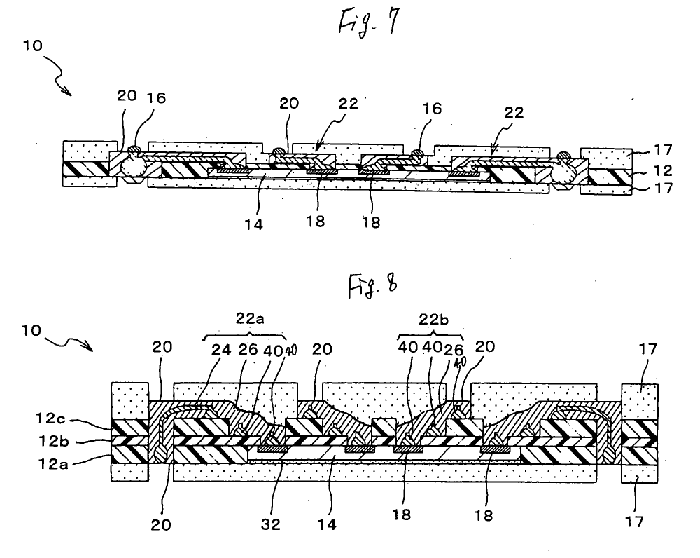

In the semiconductor devices shown in FIGS. 1 to 7, moreover, the insulating layer 12 to be a single layer is formed. By causing the insulating layer to be a multilayer, the wiring pattern 22 can be complicated. The exemplary embodiment is shown in FIG. 8.

In a semiconductor device shown in FIG. 8, three insulating layers 12a, 12b and 12c are formed and a wiring pattern 22 for electrically connecting each of electrode terminals 18, 18 . . . of a semiconductor element 14 embedded in the insulating layer 12a to be a lowermost layer to a land portion 20 on which a solder ball 16 to be an external connecting terminal is to be formed is provided beyond the insulating layers 12b and 12c. In the wiring pattern 22, a wiring pattern 22a electrically connects the electrode terminal 18 to the land portions 20 and 20 provided on both surface sides of a semiconductor device 10 and a wiring pattern 22b electrically connects the electrode terminal 18 to the land portion 20 provided above an upper surface side of the semiconductor element 14.

In the wiring pattern 22a, bumps 40 and 40 provided on exposed surfaces of the electrode terminal 18 and the insulating layer 12b and formed of gold and a wire 24 formed of gold to connect the insulating layer 12c to the land portion 20 on a lower surface side of the semiconductor device 10 are disposed in a plating metal 26 formed of copper.

In the wiring pattern 22b, moreover, the bumps 40 and 40 provided on the exposed surfaces of the electrode terminal 18 and the insulating layers 12b and 12c and formed of gold are disposed in the plating metal 26 formed of copper.

In the semiconductor device 10 shown in FIG. 8, thus, since the wiring patterns 22a and 22b are mainly formed by the plating metal 26 constituted by the copper, they have the same electrical characteristic as a wiring pattern constituted by only the copper. In addition, in the wiring pattern 22a, the wire 24 and the bumps 40 and 40 erected on the electrode terminal 18 and the insulating layer 12b are provided in the plating metal 26. Also in the wiring pattern 22b, the bumps 40 erected on the electrode terminal 18 and the insulating layers 12b and 12c are provided in the plating metal 26. Therefore, it is possible to eliminate a possibility that the wiring patterns 22a and 22b might be disconnected even if a stress caused by a difference in a coefficient of thermal expansion among the insulating layers 12a, 12b and 12c is applied. As a result, it is possible to enhance a reliability of the semiconductor device 10 shown in FIG. 8.

In the semiconductor device 10 shown in FIG. 8, moreover, the semiconductor element 14 is embedded in the insulating layer 12a to be a lowermost layer. As compared with a related-art semiconductor device in which a semiconductor element is mounted on an insulating plate, therefore, it is possible to reduce a thickness more greatly.

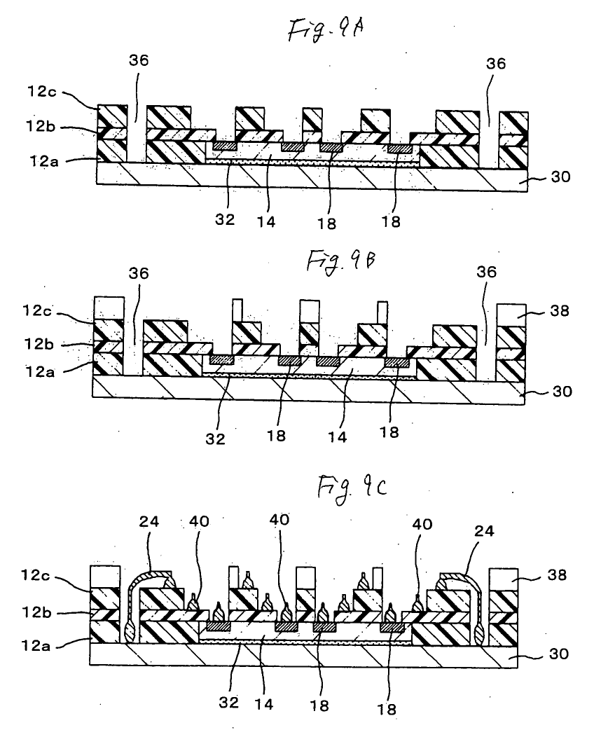

When manufacturing the semiconductor device shown in FIG. 8, first of all, two insulating layers 12b and 12c are provided on an insulating layer 12a to be a lowermost layer in which a semiconductor element 14 bonded and mounted onto one surface side of a metallic support plate 30 with an adhesive is embedded as shown in FIG. 9A. Concave portions 36 and 36 having bottom faces to which the support plate 30 is exposed are formed in the vicinity of an outer peripheral edge of each of the insulating layers 12a, 12b and 12c, and patterning is carried out through etching or a laser in such a manner that each of electrode terminals 18, 18 of the semiconductor element 14 is exposed and a part of the insulating layer 12b in the vicinity of each of the electrode terminals 18, 18 which are exposed is exposed.

A metallic thin film (not shown) is formed on the exposed surfaces of the insulating layers 12a, 12b and 12c subjected to the patterning, the exposed surface of the electrode terminal 18 and the exposed surface of the support plate 30 through nonelectrolytic plating or evaporation. As shown in FIG. 9B, then, patterns conforming to wiring patterns 22, 22 are formed on the insulating layers 12a, 12b and 12c through a plating resist 38.

As shown in FIG. 9C, next, a wire 24 having one of ends connected to the exposed surface of the metallic thin film (not shown) of the insulating layer 12c exposed to the vicinity of the concave portion 36 is extended to the exposed surface of the support plate 30 exposed to a bottom face of the concave portion 36. The other end of the wire 24 is welded and fused to the exposed surface of the support plate 30 which is exposed to the bottom face of the concave portion 36. For this reason, the other end of the wire 24 welded to the exposed surface of the support plate 30 is formed into a thicker spherical portion than the wire 24.

Moreover, bumps 40, 40 . . . are erected on exposed surfaces of the electrode terminal 18 of the semiconductor element 14 and the metallic thin film formed on the insulating layers 12b and 12c. It is possible to form the bump 40 by welding one of the ends of the wire 24 to a predetermined exposed surface of the metallic thin film and then heating and tearing the wire 24.

For the connection and extension of the wire 24 and the formation of the bump 40, it is possible to employ a bonding apparatus to be used at a wire bonding step in a process for manufacturing a semiconductor device.

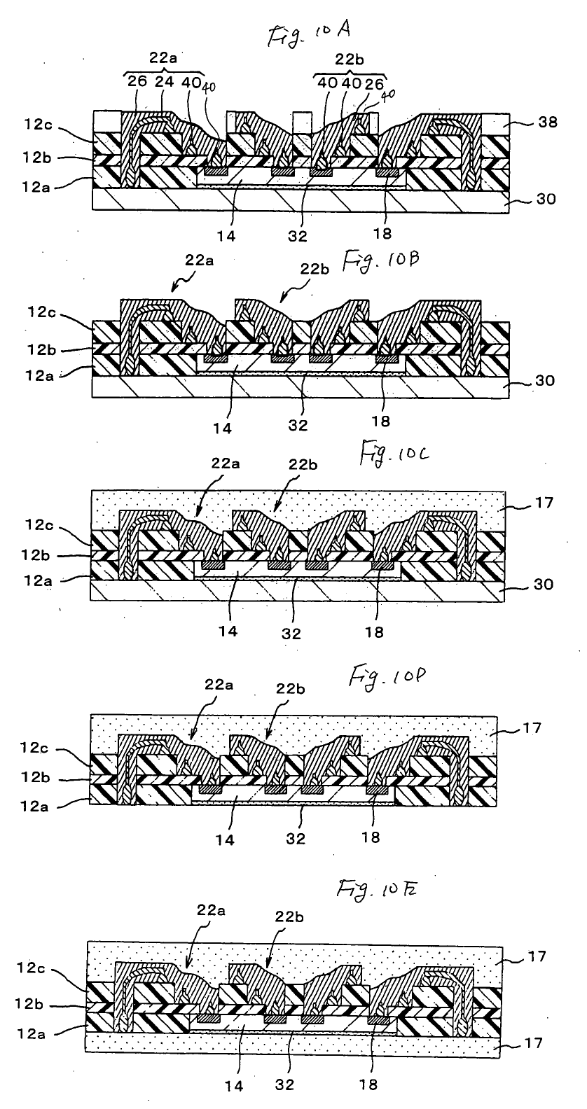

Plating copper is filled as a plating metal 26 in a pattern formed by a plating resist 38 through electrolytic copper plating using the support plate 30 and the metallic thin film as power feeding layers to form wiring patterns 22a and 22b on the exposed surfaces of the metallic thin films of the insulating layers 12a, 12b and 12c provided with the wire 24 and the bump 40 as shown in FIG. 9C [a step in FIG. 10A].

After the electrolytic copper plating for forming the wiring patterns 22a and 22b is carried out, the plating resist 38 is removed and the metallic thin film (not shown) exposed to the surface of the insulating layer 12c is removed by etching [a step in FIG. 10B]. By the removal of the metallic thin film, each of middle portions of the wiring patterns 22a and 22b can be insulated electrically.

After the exposed surface of the insulating layer 12c from which the metallic thin film is removed and the wiring patterns 22a and 22b are covered with a solder resist 17, the support plate 30 is removed by the etching [steps in FIGS. 10C and 10D].

Subsequently, the exposed surface of the insulating layer 12 which is exposed by the removal of the support plate 30 is covered with the solder resist 17 [a step in FIG. 10E]. Then, the solder resists 17 and 17 are subjected to patterning to expose land portions 20, 20 . . . . Consequently, it is possible to obtain the semiconductor device 10 shown in FIG. 8.

In the semiconductor device 10 shown in FIG. 8, the land portions 20, 20 . . . are formed on both surface sides. A solder ball 16 to be an external connecting terminal can be provided as shown in FIG. 1A on each of exposed surfaces of the land portions 20, 20 provided on a surface side of the semiconductor element 14 on which the electrode terminals 18, 18 . . . are formed.

On the other hand, the solder ball 16 may be provided in the land portions 20, 20 formed on an opposite surface side to the surface of the semiconductor element 14 on which the electrode terminals 18, 18 are formed or an external connecting terminal of an electronic component of other semiconductor devices may be connected thereto.

At the step in FIG. 10D in which the support plate 30 is removed, a part of the support plate 30 can also be left as the bump 35 as shown in FIG. 6A.

In the above-mentioned embodiments of the present invention, gold is used for the wire 24; however, for example, aluminum can be used for the wire.

While the present invention has been described with respect to a limited number of embodiments, those skilled in the art, having benefit of this disclosure, will appreciate that other embodiments can be devised which do not depart from the scope of the present invention as disclosed herein. Accordingly, the scope of the present invention should be limited only by the attached claims.

What is claimed is:

1. A semiconductor device comprising:
an insulating layer formed by a resin forming a substrate;
a semiconductor element embedded in the insulating layer;
a wiring pattern formed on the insulating layer and electrically connecting an electrode terminal of the semiconductor element and a land portion forming an external connecting terminal,
wherein the wiring pattern including the land portion is formed of a plating metal,
wherein at least one of a metallic wire having one of ends connected to the electrode terminal or the land portion and a plurality of metallic bumps erected on the insulating layer or the electrode terminal is provided in the plating metal along the wiring pattern.

2. The semiconductor device according to claim 1, wherein the wiring pattern is formed of a plating metal having a lower specific resistance than metals forming the wire and the bump.

3. The semiconductor device according to claim 1, wherein the wire is connected to the electrode terminal of the semiconductor element and the land portion forming the external connecting terminal.

4. The semiconductor device according to claim 1, wherein the bump is formed by using a metallic wire.

5. The semiconductor device according to claim 1, wherein the land portion forming the external connecting terminal is also formed on an opposite surface side to an electrode terminal formation surface on which the electrode terminal of the semiconductor element is formed.

6. The semiconductor device according to claim 1, wherein an area of the electrode terminal formation surface on which the electrode terminal of the semiconductor element is formed is smaller than an area of an external connecting terminal formation surface of the substrate on which the external connecting terminal is formed.

7. A method of manufacturing a semiconductor device comprising steps of:
mounting a semiconductor element on one surface side of a support plate, embedding the semiconductor element in an insulating layer formed by a resin forming a substrate, and then carrying out patterning over the insulating layer to expose an electrode terminal of the semiconductor element;
forming a metallic thin film on a whole surface of the insulating layer including an exposed surface of the electrode terminal, and then disposing at least one of a metallic wire having one of ends connected to the electrode terminal or a portion in which a land portion forming an external connecting terminal is to be formed and a plurality of metallic bumps erected on the insulating layer or the electrode terminal along a shape of a wiring pattern to be formed; and
forming the wiring pattern formed of a plating metal in which at least one of the wire and the bump is disposed through electrolytic plating using the metallic thin film as a power feeding layer so that the electrode terminal and the land portion are electrically connected to each other through the wiring pattern.

8. The method of manufacturing a semiconductor device according to claim 7, wherein the wiring pattern is formed of a plating metal having a lower specific resistance than the metals forming the wire and the bump.

9. The method of manufacturing a semiconductor device according to claim 7, wherein the wire has one of ends connected to the electrode terminal of the semiconductor element, and the other end of the wire is extended to a portion in which the land portion for the external connecting terminal is to be formed.

10. The method of manufacturing a semiconductor device according to claim 7, wherein the bump is formed by using the metallic wire.

11. The method of manufacturing a semiconductor device according to claim 7, wherein the land portion forming the external connecting terminal is also formed on an opposite surface side to an electrode terminal formation surface on which the electrode terminal of the semiconductor element is formed.

12. The method of manufacturing a semiconductor device according to claim 7, wherein a semiconductor element having a smaller area of the electrode terminal formation surface on which the electrode terminal is formed than an area of an external connecting terminal formation surface of the substrate forming the external connecting terminal is used as the semiconductor element.
